(19) United States
(12) Patent Application Publication
(10) Pub. No.: US 2022/0302339 A1
(43) Pub. Date: Sep. 22, 2022

(54) LED TRANSFER MATERIALS AND PROCESSES

(71) Applicant: Applied Materials, Inc., Santa Clara, CA (US)

(72) Inventors: Hou T. Ng, Campbell, CA (US); Nag Patibandla, Pleasanton, CA (US); Uma Sridhar, Sunnyvale, CA (US); Sivapackia Ganapathiappan, Los Atos, CA (US); Mingwei Zhu, San Jose, CA (US)

(73) Assignee: Applied Materials, Inc., Santa Clara, CA (US)

(21) Appl. No.: 17/671,235

(22) Filed: Feb. 14, 2022

Related U.S. Application Data
(60) Provisional application No. 63/161,820, filed on Mar. 16, 2021.

(51) Int. Cl. H01L 33/00; H01L 25/075; H01L 33/62

(52) U.S. Cl. CPC H01L 33/0093; H01L 25/0753; H01L 33/62; H01L 2933/0066

(57) ABSTRACT

Exemplary processing methods of forming an LED structure on a backplane may include coupling a first transfer substrate with an LED source substrate. The LED source substrate may include a plurality of fabricated LEDs. The coupling of the first transfer substrate may be produced with a first coupling material extending between the first transfer substrate and each LED of the plurality of fabricated LEDs. The methods may include separating the LED source substrate from the LEDs. The methods may include coupling a second transfer substrate with the first transfer substrate. The coupling of the first transfer substrate may be produced with a second coupling material extending between the second transfer substrate and each LED of the plurality of fabricated LEDs. The methods may include separating the first transfer substrate from the second transfer substrate. The methods may include bonding the plurality of fabricated LEDs with a display backplane.

### CROSS-REFERENCE TO RELATED APPLICATIONS

This application claims the benefit of, and priority to U.S. Provisional Application Ser. No. 63/161,820, filed Mar. 16, 2021, which is hereby incorporated by reference in its entirety for all purposes.

### TECHNICAL FIELD

The present technology relates to semiconductor processing and materials. More specifically, the present technology relates to transfer processes and materials for LED components.

### BACKGROUND

LED display panels may be formed with a number of light sources that operate as pixels on the display. The pixels may be formed with monochromatic light sources that are then filtered to produce color, or the pixels may each have individual red, blue, and green light sources formed. In either scenario, millions of light sources may be formed and connected with a backplane for operation. As device sizes continue to grow, while pixels reduce to the micro or smaller scale, alignment and transfer operations may be challenged, which may impact the ability to produce reliable display devices.

Thus, there is a need for improved systems and methods that can be used to produce high quality devices and structures. These and other needs are addressed by the present technology.

### SUMMARY

Exemplary processing methods of forming an LED structure on a backplane may include coupling a first transfer substrate with an LED source substrate. The LED source substrate may include a plurality of fabricated LEDs. The coupling of the first transfer substrate may be produced with a first coupling material extending between the first transfer substrate and each LED of the plurality of fabricated LEDs. The methods may include separating the LED source substrate from the plurality of fabricated LEDs. The methods may include coupling a second transfer substrate with the first transfer substrate. The coupling of the first transfer substrate may be produced with a second coupling material extending between the second transfer substrate and each LED of the plurality of fabricated LEDs. The methods may include separating the first transfer substrate from the second transfer substrate. The methods may include bonding the plurality of fabricated LEDs with a display backplane.

In some embodiments, the second transfer substrate and a substrate supporting the display backplane may be characterized by a coefficient of thermal expansion difference of less than or about 20%. The second transfer substrate and the substrate supporting the display backplane may each be or include glass, silicon, or a polymeric material. Separating the LED source substrate from the plurality of fabricated LEDs may include directing a laser through a backside of the LED source substrate to decouple the LED source substrate from the plurality of fabricated LEDs. The first coupling material may be characterized by an onset or release temperature of greater than or about 100° C. The second coupling material may be characterized by an onset or release temperature of greater than or about 150° C. The second coupling material may be characterized by an onset or release temperature greater than a melting temperature of contacts on each LED of the plurality of fabricated LEDs. The first coupling material and the second coupling material each may be one of an adhesive material, a polymeric organosilicon material, or a UV release polymer. The first coupling material and the second coupling material may be the same material. At least one of the first coupling material and the second coupling material may be an acrylic adhesive material. A thickness of the first coupling material and the second coupling material may be less than or about 100 μm.

Embodiments of the present technology may encompass methods of forming an LED structure on a backplane. The methods may include coupling a first transfer substrate with a first surface of each LED of a plurality of fabricated LEDs by a first coupling material. The first surface of each LED of the plurality of fabricated LEDs may include a metal contact. A second surface of each LED of the plurality of fabricated LEDs opposite the first surface of each LED may be coupled with an LED source substrate. The methods may include separating the LED source substrate from the second surface of each LED of the plurality of fabricated LEDs. The methods may include coupling a second transfer substrate with the second surface of each LED of the plurality of fabricated LEDs by a second coupling material. The methods may include separating the first transfer substrate from the second transfer substrate. Each LED of the plurality of fabricated LEDs may be retained with the second transfer substrate. The methods may include bonding the first surface of each LED of the plurality of fabricated LEDs with a display backplane.

In some embodiments, the first coupling material and the second coupling material each may be one of an adhesive material, a polymeric organosilicon material, or a UV release polymer. At least one of the first coupling material and the second coupling material may be a heat-expandable adhesive material characterized by a release temperature below a melting temperature of the metal contact. At least one of the first coupling material and the second coupling material may be a heat-expandable adhesive material characterized by a release temperature above a melting temperature of the metal contact. The second transfer substrate and a substrate supporting the display backplane may be characterized by a coefficient of thermal expansion difference of less than or about 20%.

Some embodiments of the present technology may encompass methods of forming an LED structure on a backplane. The methods may include coupling a first transfer substrate with a first surface of each LED of a plurality of fabricated LEDs by a first coupling material. The first surface of each LED of the plurality of fabricated LEDs may include a metal contact. A second surface of each LED of the plurality of fabricated LEDs opposite the first surface of each LED may be coupled with a sapphire substrate. The methods may include separating the sapphire substrate from the second surface of each LED of the plurality of fabricated LEDs with a laser lift-off process. The methods may include coupling a second transfer substrate with the second surface of each LED of the plurality of fabricated LEDs by a second coupling material. The methods may include separating the first transfer substrate from the second transfer substrate. Each LED of the plurality of fabricated LEDs may be retained with the second transfer substrate. The methods may include bonding the first surface of each LED of the plurality of fabricated LEDs with a display backplane. The second transfer substrate and a substrate supporting the display backplane may be characterized by a coefficient of thermal expansion difference of less than or about 20%. The methods may include separating the second transfer substrate from the substrate supporting the backplane.

In some embodiments, a thickness of the first coupling material and the second coupling material may be less than or about 100 μm. Separating the sapphire substrate from the plurality of fabricated LEDs may include directing a laser through a backside of the sapphire substrate to decouple the sapphire substrate from the plurality of fabricated LEDs. The first coupling material and the second coupling material each may be one of an adhesive material, a polymeric organosilicon material, or a UV release polymer.

Such technology may provide numerous benefits over conventional systems and techniques. For example, the present technology may provide a method for transferring LEDs to a backplane that may readily be scaled to large form factors. Additionally, processes according to embodiments of the present technology may provide a high transfer reliability to accommodate vertical offset between LED contacts. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows selected operations in a method of forming an airgap in a semiconductor structure according to some embodiments of the present technology.

FIGS. 2A-2G illustrate schematic views of substrate materials during selected operations performed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Fabrication of display panels may include a number of operations for transferring LEDs from a substrate on which they are grown to a display backplane, which may be on a separate substrate. The LEDs may be formed on an LED substrate, such as sapphire or some other base material before being separated from the LED substrate to be coupled with the backplane. An ideal operation for transferring the LEDs may simply be to invert the LED substrate, and bond the LEDs to associated contacts on the backplane. Depending on the contact materials and at what temperatures they may melt, the bonding process may be performed at temperatures between 100° C. and 200° C. or more. However, the substrate on which the backplane is formed may be a different material than the substrate on which the LEDs are formed, and the two materials may be characterized by different coefficients of thermal expansion. If left unaddressed, the differing expansions may cause misalignment of the LEDs, which may cause reduced yield, and may lead to scrapped materials.

Conventional technologies may perform alternative processes for transferring the LEDs to the backplane, and may perform one or more pick-and-place operations. For example, some conventional technologies may use a stamp or other sheer transfer process to separate the LEDs and then reapply the LEDs on the backplane. However, these processes are often limited to a reduced scale in order to ensure alignment across the substrates and maintain precision of the process. Additionally, many of these processes are incapable of addressing height offsets of the LEDs on the LED substrate, which may cause certain LEDs to not be properly coupled with the backplane during transfer.

The present technology may overcome these issues by performing a double-transfer process that utilizes materials to accommodate wider defect tolerances by coupling pliant materials with more rigid supports, with both of which being scalable to large substrates to increase throughput. Although the remaining disclosure will routinely identify specific LED materials and processes utilizing the disclosed technology, it will be readily understood that the systems and methods are equally applicable to a variety of materials and processes as may occur for producing displays. Accordingly, the technology should not be considered to be so limited as for use with etching processes alone.

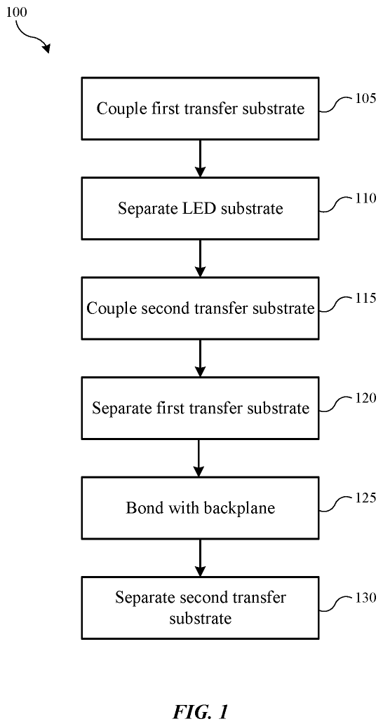

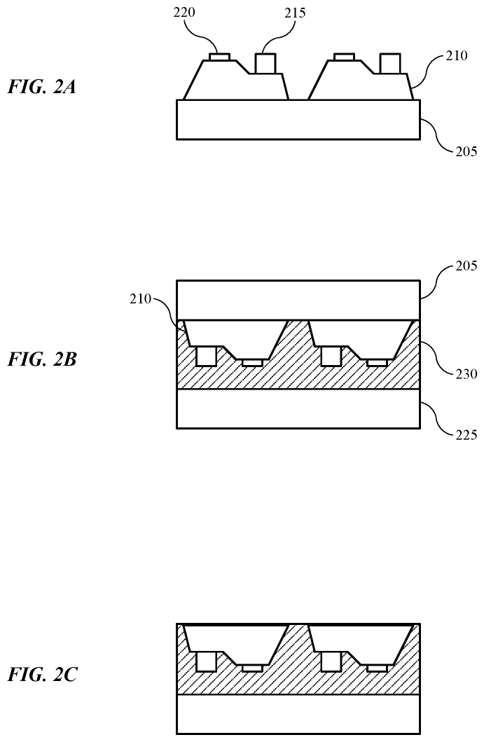

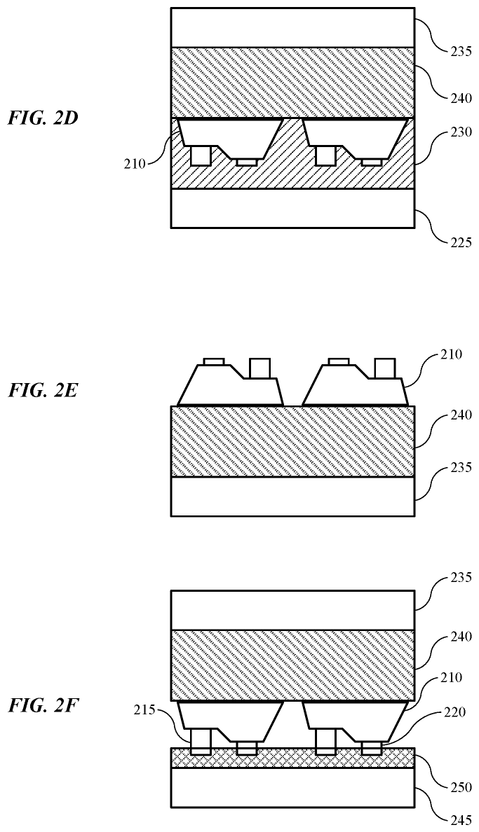

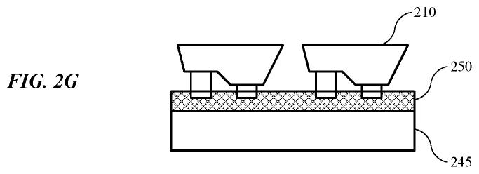

FIG. 1 illustrates selected operations of a fabrication method 100 for coupling LEDs with a backplane. Method 100 may include one or more operations prior to the initiation of the method, including front end processing, deposition, etching, polishing, cleaning, or any other operations that may be performed prior to the described operations. The method may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 100 describes operations shown schematically in FIGS. 2A-2G, the illustrations of which will be described in conjunction with the operations of method 100. It is to be understood that FIGS. 2A-2G illustrate only partial schematic views, and a substrate may contain any number of LED sections having aspects as illustrated in the figures, as well as alternative structural aspects that may still benefit from aspects of the present technology.

Method 100 may involve optional operations to develop the structure to a particular fabrication operation. As illustrated in FIG. 2A, an LED source substrate 205 may have a plurality of LEDs 210 formed or grown overlying the substrate. Although only 2 LEDs 210 are illustrated, it is to be understood that a substrate may have hundreds, thousands, millions, or more LEDs formed, and which may be any size, as the present technology may encompass microLEDs among any other types of LED structure. Substrate 205 may be any substrate on which structures may be formed, such as silicon materials, aluminum materials, including sapphire, or any other materials as may be used in display or semiconductor fabrication. The LEDs 210 may be characterized by any shape or structure, and may be formed as monochromatic LED structures, or specific RGB or other LED structures. As illustrated, the LED structures may have a stepped profile as illustrated, or any other structure. Along a first surface opposite a second surface coupled with the source substrate 205, one or more contacts may be formed or may extend from the LED. For example, a first contact 215, such as an N-contact, and a second contact 220, such as a P-contact may extend from the first surface of the LED. The contacts may be made of any metal, alloy, or conductive material in embodiments encompassed by the present technology. The contacts may be formed to a substantially similar height, although variation may occur among the LEDs formed across the substrate.

Method 100 may include coupling a first transfer substrate with the LED source substrate 205 at operation 105. As illustrated in FIG. 2B, LED source substrate 205 may be inverted, although it is to be understood that the reverse may occur. Regardless of orientation, a first transfer substrate 225 may be coupled with the LED source substrate. The first transfer substrate 225 may be any number of substrate materials as described elsewhere in this disclosure, and in some embodiments may be glass, silicon, a polymeric material, or any other material used in semiconductor or display technology. However, because the first transfer substrate may be an intermediary, glass or some other general purpose substrate may be sufficient. A first coupling material 230 may be used to produce the coupling. The first coupling material 230 may be included and extend between the first transfer substrate 225 and each LED 210 of the plurality of fabricated LEDs. Although illustrated as extending fully to LED source substrate 205, first coupling material 230 may extend to any height or depth of the LEDs 210, although may extend fully beyond a step when included on the LEDs to ensure all contacts are covered by the first coupling material in some embodiments.

The first coupling material may be or include a number of materials that may be flowable or deformable to extend about the LEDs 210. For example, materials may be applied along first transfer substrate 225, or along LEDs 210 and LED source substrate 205, depending on the flowability of the material. For example, coupling material 230 may be or include any adhesive material or any polymeric material, such as any number of viscoelastic materials. In some embodiments, the first coupling material may be formed across the LED source substrate to ensure uniformity and complete covering, such as may be applied by blade coating, spray coating, or any other application mechanism. Some materials that may have sufficient flow properties may be applied to either substrate. For example, first coupling material 230 may be a polymeric organosilicon material, which may sufficiently flow across the LED source substrate to allow application across the LEDs followed by coupling/curing with the first transfer substrate. Exemplary materials may include any number of polymerized siloxane materials, such as including polydimethylsiloxane.

Additional materials may include UV release adhesives or heat-expandable adhesives that may be applied across the first transfer substrate. The LED source substrate may be compressed against the adhesive material to engage the adhesive with the LEDs. The materials may include any number of materials that may operate as adhesives to maintain engagement of the LEDs during separation from the LED source substrate as will be explained below. Additionally, the materials may be releasable with an application of ultraviolet light, heating, or sheer force. Exemplary materials may include acrylic-based materials, rubber materials, silicone or siloxane based materials, as well as any number of other polymeric materials, which may include materials incorporating polyamide, polyester, urethane, styrene, vinyl, or any other moieties in any combination. The materials may also include additional agents or components to increase adhesion, during operation, as well as to improve release. For example, the materials may include a foaming agent such as heat-expandable shells or shells that may melt at designated temperature to release a gas or other expansion material.

The first coupling material may be applied to any thickness. As non-limiting examples, for microLED structures, the first coupling material may be applied to a thickness of greater than or about 1 μm, and may be applied to a thickness of greater than or about 3 μm, greater than or about 5 μm, greater than or about 10 μm, greater than or about 20 μm, greater than or about 30 μm, greater than or about 40 μm, greater than or about 50 μm, greater than or about 60 μm, greater than or about 70 μm, greater than or about 80 μm, greater than or about 90 μm, greater than or about 100 μm, or more. The thickness may be sufficient to ensure each contact is engaged within the coupling material in some embodiments. Having increased thickness may ensure that the bulk of the coupling material may remain below a threshold temperature, such as during a separation of the LED source substrate as will be described below. Additionally, thicker applications may accommodate substrate bowing, as may occur with sapphire substrates. However, thicker films may be more likely to lose co-planarity after release, and thus in some embodiments the first coupling material may be applied to a thickness of less than or about 200 μm, and may be applied to a thickness of less than or about 150 μm, less than or about 100 μm, or less.

After the first coupling material is sufficiently applied and/or cured, the LED source substrate may be separated from the plurality of fabricated LEDs at operation 110. As shown in FIGS. 2B and 2C, the separation may be performed through a backside of the LED source substrate in some embodiments, in order to separate the base LED structure from the substrate. Any number of separation techniques may be performed including mechanical and energy-enhanced separation. As one non-limiting example, in some embodiments a laser lift-off process may be performed. For example, the backside of the LEDs, such as along a second surface coupled with the LED source substrate 205, may be any number of semiconductor materials, such as or including gallium nitride, although any other materials used in LED fabrication may similarly be used. As noted above, although LED source substrate 205 may be any number of materials, in some embodiments LED source substrate 205 may be sapphire. The separation process may include directing a laser through the backside of the LED source substrate to decouple the plurality of fabricated LEDs from the LED source substrate. In operation, the laser may evaporate portions of the gallium nitride, which may separate the LEDs or sufficiently limit the contact that minimal sheer force may separate the LED source substrate from the LEDs.

First coupling material 230 may be exposed to the laser during operation, which may exceed temperatures of 500° C., 750° C., or more during the lift-off operation. The first coupling material 230 may be materials such as polydimethylsiloxane or a heat-expandable material in some embodiments, as previously noted, and which may be characterized by an adhesive stability up to a specified threshold at which onset of release may occur, such as including degradation of the polymeric structure or expansion of constituent materials. In some embodiments, the onset temperature for release of the first coupling material may be less than or about 200° C., and may be less than or about 190° C., less than or about 180° C., less than or about 170° C., less than or about 160° C., less than or about 150° C., less than or about 140° C., less than or about 130° C., less than or about 120° C., less than or about 110° C., less than or about 100° C., or less. Consequently, the laser lift-off operation may expose regions of the first coupling material, such as between LEDs, to temperatures exceeding onset of release.

Compensating for this aspect may be achieved in multiple ways. For example, the laser lift-off operation may be performed for a period of time during which exposure of the first coupling material at any location may be limited to a time of less than or about 100 μsec, and may be limited to a time of less than or about 75 μsec, less than or about 50 μsec, less than or about 25 μsec, less than or about 10 μsec, or less. Additionally, by maintaining a thickness of the first coupling material to be greater than or about 10 μm, and which may be greater than or about 50 μm, a bulk temperature of the first coupling material may be maintained below the onset temperature for release during the lift-off process. Similarly, for some materials, such as polydimethylsiloxane or other organic siloxane materials, degradation may at least partially occur due to the formation of carbon dioxide, which may outgas from the material, and which may occur due to the presence of oxygen in the processing environment. Consequently, although in some embodiments the separation process may be performed in an ambient environment, in some embodiments the process may be performed in an inert environment, such as a nitrogen-environment or some other oxygen-starved environment, which may further limit or prevent degradation of the first coupling material.

Once the LED source substrate has been separated from the LEDs, the plurality of fabricated LEDs 210 may be inverted with respect to the first transfer substrate, as illustrated in FIG. 2C. Hence, method 100 may include coupling a second transfer substrate with the first transfer substrate at operation 115. As shown in FIG. 2D, second transfer substrate 235 may include a second coupling material 240, which may extend along a second surface or backside of each LED of the plurality of LEDs 210, and may extend between the second transfer substrate and the LEDs. Second transfer substrate 235 may be or include any of the materials previously described, including glass, a silicon-containing material, a polymeric or plastic material, or any other substrate on which semiconductor or display processing may occur. As will be described below, because second transfer substrate 235 may be included during a subsequent bonding process, second transfer substrate 235 may be a material that is thermally compatible with a backplane substrate.

Second coupling material 240 may be any of the coupling materials previously described, and may be the same material as the first coupling material, a different version of a similar material as the first coupling material, or a different material from the first coupling material in some embodiments of the present technology. At operation 120, the first transfer substrate may be separated from the second transfer substrate, which may expose the metal contacts on the LEDs 210 as illustrated in FIG. 2E. As shown in the figure, LEDs 210 may be retained on the second coupling material 240 associated with second transfer substrate 235. To ensure that the second coupling material is retained during the separation operation, in some embodiments the second coupling material may include one or more characteristic differences from the first coupling material.

Subsequent processing as will be described below may include a bonding operation that may be performed at elevated temperatures. Accordingly, the second coupling material may be exposed to temperatures to which the first coupling material may be exposed. Hence, in some embodiments the second coupling material may be better suited to a bonding process compared to the first coupling material. For example, in some embodiments the second coupling material may be or include a more resilient material, such as a UV release polymer, or a heat-expandable adhesive characterized by a stability for adhesion at temperatures greater than or about a temperature at which a bonding process may occur. For example, the second coupling material may be characterized by an expansion or release onset temperature of greater than or about 100° C., and may be characterized by a release onset temperature of greater than or about 130° C., greater than or about 150° C., greater than or about 170° C., greater than or about 200° C., or greater, including any of the temperatures or ranges stated previously.

Hence, in some embodiments of the present technology, by utilizing materials characterized by different release temperatures, heat-expandable materials may be used for each of the first coupling material and the second coupling material. For example, the first coupling material may be characterized by a release onset temperature of greater than or about 100° C., but less then or about 150° C. This may facilitate maintaining the first coupling material during application of the laser lift-off process, while allowing the first coupling material to be removed at a temperature lower than a melting temperature of the metal contacts of the LEDs. Additionally, the second coupling material may be characterized by a release onset temperature of greater than or about 150° C., greater than or about 170° C., greater than or about 200° C., or more, which may facilitate maintaining the second coupling material during a bonding process. Additional non-limiting examples may include utilizing polydimethylsiloxane for the first coupling material or second coupling material, and/or utilizing a UV release polymer for the first coupling material or second coupling material. A variety of other materials may be used in embodiments of the present technology, and which may be characterized by any of the properties as explained above for the first coupling material or the second coupling material.

After the first transfer substrate is separated from the second transfer substrate, a bonding operation may be performed at operation 125. As shown in FIG. 2F, second transfer substrate 235 may be used to align LEDs 210 with a backplane 250 for a display, and which may be formed on a substrate 245. The contacts 215 and 220 of the LEDs may be aligned with corresponding contacts of the backplane as illustrated. A bonding process may be performed, which may include, among any number of bonding operations, forming a eutectic bond between the contact materials if different, or forming a solid connection between the contacts. As one non-limiting example, the LED contacts may be or include indium, which may melt at about 156° C., by applying heat to the substrate 245, the contact connection may be raised above the melting point of the contacts, which may bond the contacts. As noted previously, this may cause both the backplane substrate 245 and the second transfer substrate 235 to be heated. Based on the coefficient of thermal expansion of the substrate materials, the substrates may expand to different degrees, which may impact alignment during the bonding process, and can reduce yield for the LED connections. Similarly, pressure may be applied to the one or both substrates during the bonding process, which may lower the melting temperature of the contact materials, and may ensure the bonding may be performed below the release onset temperature of the second coupling material.

Accordingly, in some embodiments of the present technology, the second transfer substrate and the backplane substrate may either be the same material, or may be two different materials that are characterized by a difference in coefficient of thermal expansion of less than or about 25%, and may be characterized by a difference of less than or about 20%, less than or about 15%, less than or about 12%, less than or about 10%, less than or about 9%, less than or about 8%, less than or about 7%, less than or about 6%, less than or about 5%, less than or about 4%, less than or about 3%, less than or about 2%, less than or about 1%, or less. For example, an initial sapphire substrate on which the LEDs are formed may be characterized by a coefficient of thermal expansion of 8×10⁻⁶ m/(m·K) or higher, while a glass substrate on which the backplane is formed may be characterized by a coefficient of thermal expansion of 6×10⁻⁶ m/(m·K) or lower. Consequently, as the components are heated, the alignment between the contacts may shift. However, by utilizing a second transfer substrate that is the same material as the backplane substrate, or is a material characterized by a more similar coefficient of thermal expansion, alignment may be maintained and may provide increased yield.

After the bonding has been completed for the LEDs across the display backplane, method 100 may include separating the second transfer substrate from the LEDs at operation 130. As illustrated, in FIG. 2G, the second transfer substrate may be removed from the plurality of LEDs by releasing the second coupling material from the second surface or backside of the LEDs. Depending on the release mechanism for the second coupling material, the process may include directing UV or other energy or light through a backside of the second transfer substrate, or heating the second transfer substrate to an onset temperature for release of the second transfer substrate. As previously noted, the onset temperature for release of the second transfer substrate may in some embodiments of the present technology be higher than a melting temperature of the metal of the LED contacts. Accordingly, in some embodiments for which a heat-expandable adhesive is utilized, the heating operation for release may be performed on the second transfer substrate to limit heat transfer to the LED contacts. Once the second transfer substrate has been released, the LED and backplane structure may be complete. By utilizing processes and materials according to embodiments of the present technology, alignment may be better maintained during LED bonding operations, which may provide increased yield over conventional technologies.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either limit of the range, both limits of the range, or neither limit of the range are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the LED” includes reference to one or more LEDs and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of forming an LED structure on a backplane, the method comprising:
coupling a first transfer substrate with an LED source substrate, wherein the LED source substrate comprises a plurality of fabricated LEDs, and wherein the coupling of the first transfer substrate is produced with a first coupling material extending between the first transfer substrate and each LED of the plurality of fabricated LEDs;
separating the LED source substrate from the plurality of fabricated LEDs;
coupling a second transfer substrate with the first transfer substrate, wherein the coupling of the second transfer substrate is produced with a second coupling material extending between the second transfer substrate and each LED of the plurality of fabricated LEDs;
separating the first transfer substrate from the second transfer substrate; and
bonding the plurality of fabricated LEDs with a display backplane.

2. The method of forming an LED structure on a backplane of claim 1, wherein the second transfer substrate and a substrate supporting the display backplane are characterized by a coefficient of thermal expansion difference of less than or about 20%.

3. The method of forming an LED structure on a backplane of claim 2, wherein the second transfer substrate and the substrate supporting the display backplane each comprise glass, silicon, or a polymeric material.

4. The method of forming an LED structure on a backplane of claim 1, wherein separating the LED source substrate from the plurality of fabricated LEDs comprises:
directing a laser through a backside of the LED source substrate to decouple the LED source substrate from the plurality of fabricated LEDs.

5. The method of forming an LED structure on a backplane of claim 1, wherein the first coupling material is characterized by an onset or release temperature of greater than or about 100° C.

6. The method of forming an LED structure on a backplane of claim 5, wherein the second coupling material is characterized by an onset or release temperature of greater than or about 150° C.

7. The method of forming an LED structure on a backplane of claim 6, wherein the second coupling material is characterized by an onset or release temperature greater than a melting temperature of contacts on each LED of the plurality of fabricated LEDs.

8. The method of forming an LED structure on a backplane of claim 1, wherein the first coupling material and the second coupling material are each one of an adhesive material, a polymeric organosilicon material, or a UV release polymer.

9. The method of forming an LED structure on a backplane of claim 8, wherein the first coupling material and the second coupling material are the same material.

10. The method of forming an LED structure on a backplane of claim 8, wherein at least one of the first coupling material and the second coupling material is an acrylic adhesive material.

11. The method of forming an LED structure on a backplane of claim 1, wherein a thickness of the first coupling material and the second coupling material is less than or about 100 μm.

12. A method of forming an LED structure on a backplane, the method comprising:
coupling a first transfer substrate with a first surface of each LED of a plurality of fabricated LEDs by a first coupling material, wherein the first surface of each LED of the plurality of fabricated LEDs comprises a metal contact, and wherein a second surface of each LED of the plurality of fabricated LEDs opposite the first surface of each LED is coupled with an LED source substrate;
separating the LED source substrate from the second surface of each LED of the plurality of fabricated LEDs;
coupling a second transfer substrate with the second surface of each LED of the plurality of fabricated LEDs by a second coupling material;
separating the first transfer substrate from the second transfer substrate, wherein each LED of the plurality of fabricated LEDs is retained with the second transfer substrate; and
bonding the first surface of each LED of the plurality of fabricated LEDs with a display backplane.

13. The method of forming an LED structure on a backplane of claim 12, wherein the first coupling material and the second coupling material are each one of an adhesive material, a polymeric organosilicon material, or a UV release polymer.

14. The method of forming an LED structure on a backplane of claim 13, wherein at least one of the first coupling material and the second coupling material is a heat-expandable adhesive material characterized by a release temperature below a melting temperature of the metal contact.

15. The method of forming an LED structure on a backplane of claim 13, wherein at least one of the first coupling material and the second coupling material is a heat-expandable adhesive material characterized by a release temperature above a melting temperature of the metal contact.

16. The method of forming an LED structure on a backplane of claim 12, wherein the second transfer substrate and a substrate supporting the display backplane are characterized by a coefficient of thermal expansion difference of less than or about 20%.

17. A method of forming an LED structure on a backplane, the method comprising:
coupling a first transfer substrate with a first surface of each LED of a plurality of fabricated LEDs by a first coupling material, wherein the first surface of each LED of the plurality of fabricated LEDs comprises a metal contact, and wherein a second surface of each LED of the plurality of fabricated LEDs opposite the first surface of each LED is coupled with a sapphire substrate;
separating the sapphire substrate from the second surface of each LED of the plurality of fabricated LEDs with a laser lift-off process;
coupling a second transfer substrate with the second surface of each LED of the plurality of fabricated LEDs by a second coupling material;
separating the first transfer substrate from the second transfer substrate, wherein each LED of the plurality of fabricated LEDs is retained with the second transfer substrate;
bonding the first surface of each LED of the plurality of fabricated LEDs with a display backplane, wherein the second transfer substrate and a substrate supporting the display backplane are characterized by a coefficient of thermal expansion difference of less than or about 20%; and
separating the second transfer substrate from the substrate supporting the backplane.

18. The method of forming an LED structure on a backplane of claim 17, wherein a thickness of the first coupling material and the second coupling material is less than or about 100 μm.

19. The method of forming an LED structure on a backplane of claim 17, wherein separating the sapphire substrate from the plurality of fabricated LEDs comprises:
directing a laser through a backside of the sapphire substrate to decouple the sapphire substrate from the plurality of fabricated LEDs.

20. The method of forming an LED structure on a backplane of claim 17, wherein the first coupling material and the second coupling material are each one of an adhesive material, a polymeric organosilicon material, or a UV release polymer.
